(19) United States
(12) Patent Application Publication
(10) Pub. No.: US 2009/0134020 A1
(43) Pub. Date: May 28, 2009

(54) SPUTTERING TARGET AND PROCESS FOR PRODUCING THE SAME

(75) Inventors: Yukinobu Suzuki, Kanagawa-Ken (JP); Koichi Watanabe, Kanagawa-Ken (JP); Toshiya Sakamoto, Kanagawa-Ken (JP); Michio Sato, Kanagawa-Ken (JP); Yasuo Kohsaka, Kanagawa-Ken (JP)

Correspondence Address: BURR & BROWN, PO BOX 7068, SYRACUSE, NY, 13261-7068, US

(73) Assignees: Kabushiki Kaisha Toshiba, Minato-ku, Tokyo (JP); Toshiba Materials Co., Ltd., Kanagawa-Ken (JP)

(21) Appl. No.: 12/091,832

(22) PCT Filed: Nov. 2, 2006
(86) PCT No.: PCT/JP2006/321969

§ 371 Date: Jun. 26, 2008

(30) Foreign Application Priority Data
Nov. 7, 2005 (JP) 2005-321844

(51) Int. Cl. C23C 14/34; B29C 65/00; B29C 65/02

(52) U.S. Cl. 204/298.12; 156/276

(57) ABSTRACT

There are provided a sputtering target and a process for producing a sputtering target. The sputtering target includes a first layer located on its side to be sputter treated and a second layer located on its side not to be sputter treated. The first and second layers are bonded to each other through a bonding interface between the first layer and the second layer. The sputtering target satisfying the following requirements X and Y:
requirement X: A/B≦1.5 and
requirement Y: A/C≦1.5,
   wherein A represents an oxygen peak value for the bonding interface; B represents an oxygen peak value for the first layer; and C represents an oxygen peak value for the second layer. The sputtering target is advantageous in that a spent sputtering target can be recycled to utilize resources and can form a thin film while effectively preventing the occurrence of abnormal discharge and splash.

### TECHNICAL FIELD

This invention provides a sputtering target and a process for producing the sputtering target.

### BACKGROUND ART

Sputtering is one of conventional techniques for forming a thin film on the surface of a base material. Various targets for use in sputtering have been proposed according to the type, applications or purposes and the like of a thin film to be formed, and targets formed of, for example, molybdenum (Mo) materials, tungsten (W) materials, chromium (Cr) materials, tantalum (Ta) materials, titanium (Ti) materials, aluminum (Al) materials, silicon (Si) materials, molybdenum-tungsten materials, chromium-molybdenum materials, and molybdenum-tantalum materials have been put to practical use.

Upon sputtering, the target material is started to be consumed from its surface, and the thickness of the target material is gradually reduced. Evenly sputtering the whole target material is difficult. Accordingly, the target material usually has a region where the consumption is significant, and a region where the consumption is not significant. As a result, concavoconvexes occur on the surface of the treated target material. In target materials exposed to treatment for a long period of time or target materials having a surface on which irregularities (concavoconvexes) have occurred, the formation of a good thin film with high efficiency is so difficult that the consumed target is discarded.

In general, the target material is discarded when about 15 to 40% of the weight of the whole target material has been consumed. This means that about 60 to 85% of the weight of the whole target material as a residue is discarded without being used in thin film formation.

The target material contains a large amount of expensive elements, and, thus, the reutilization of the target material has been strongly desired. Regarding techniques reutilizing a target material, for example, Japanese Patent Laid-Open No. 342562/2001 describes a technique comprising covering one or a plurality of solid blocks as a spent target material with a powder having substantially the same composition as the solid block(s) and subjecting the assembly to hot isostatic pressing (HIP) to reclaim a target material formed of a sinter. Further, for example, Japanese Patent Laid-Open No. 35919/2004 discloses another technique for reutilizing a target material, comprising bringing each of the bonding interface roughness of a spent target and the bonding interface roughness of a fresh target to Ra=not more than 100 μm and then bonding the spent target and the fresh target to each other by hot isostatic pressing (HIP) to reclaim the target material.

Patent document 1: Japanese Patent Laid-Open No. 342562/2001

Patent document 2: Japanese Patent Laid-Open No. 35919/2004

### DISCLOSURE OF INVENTION

### Problems to be Solved by the Invention

The above technique is recognized as useful as a technique for reutilizing spent target material. According to studies conducted by the present inventors, it has been found that, when a regenerated target material and a fresh unused target material are used in sputtering treatment, there is a difference, such as, in sputtering treatment stability and properties of a formed thin film between the regenerated target material and the fresh unused target material. For example, when the reclaimed target material is used, abnormal discharge is more likely to occur as compared with the fresh target material. This difference has been found to be causative of splash or the like which affects thin film formation.

This problem is particularly significant when the target material is an aluminum (Al) alloy material.

### Means for Solving Problem

It has hitherto been a common recognition that there is substantially no difference in sputtering treatment and thin film formation between a spent target material and a regenerated target material provided with a fresh target material layer on its surface for reutilization of the spent target material. According to studies conducted by the present inventors, it has been found that a bonding interface, which is clearly different from both the spent target material part and the freshly formed target material part, exists between the spent target material part and the freshly formed target material part, and the presence of the bonding interface affects abnormal discharge, splash and stable formation of the thin film.

The present inventors have found that the bonding interface is different from the spent target material part and the freshly formed target material part in oxygen peak level and that specifying the requirement for the oxygen peak level for the bonding interface and both the parts can suppress abnormal discharge and can realize stable formation of a good thin film.

Thus, according to the present invention, there is provided a sputtering target comprising: a first layer located on its side to be sputter treated and a second layer located on its side not to be sputter treated, the first layer and the second layer having been bonded to each other through a bonding interface between the first layer and the second layer, the sputtering target satisfying the following requirements X and Y:
requirement X: A/B≦1.5 and
requirement Y: A/C≦1.5,

wherein A represents an oxygen peak value for the bonding interface; B represents an oxygen peak value for the first layer; and C represents an oxygen peak value for the second layer.

The sputtering target according to present invention preferably further satisfies the following requirement Z:
requirement Z: C/B≦1.5.

In the sputtering target according to the present invention, preferably, the first layer is formed of a layered deposit produced by depositing powder of a target material, for constituting the first layer, on the bonding interface.

In the sputtering target according to the present invention, preferably, the first layer is formed of a layered deposit produced by thermally spraying and depositing powder of a target material, for constituting the first layer, on the bonding interface.

In the sputtering target according to the present invention, preferably, the first layer is formed of a plate-shaped target material for constituting the first layer.

Preferably, the sputtering target according to the present invention has been formed by diffusion bonding a target material for constituting the first layer and a target material for constituting the second layer by hot isostatic pressing (HIP).

In the sputtering target according to the present invention, preferably, the bonding interface has been formed by chemically etching the surface of a target material for constituting the second layer before the formation or bonding of the first layer.

The sputtering target according to the present invention may further comprise a further layer distinguished from the first layer and the second layer and another bonding interface provided between the first and/or second layer and the further layer.

According to the present invention, there is provided a process for producing a sputtering target comprising a first layer located on its side to be sputter treated and a second layer located on its side not to be sputter treated, the first layer and the second layer having been bonded to each other through a bonding interface between the first layer and the second layer, the sputtering target satisfying the following requirements X and Y:
requirement X: A/B≦1.5 and
requirement Y: A/C≦1.5,

wherein A represents an oxygen peak value for the bonding interface; B represents an oxygen peak value for the first layer; and C represents an oxygen peak value for the second layer,

the process being characterized by comprising chemically etching the surface of a target material for constituting the second layer after or without flattening treatment to form a chemically etched face for constituting the bonding interface, and depositing powder of a target material for constituting the first layer by thermal spraying on the chemically etched face to form a layered deposit and thus to bond the first layer and the second layer through the bonding interface.

According to the present invention, there is also provided a process for producing a sputtering target comprising a first layer located on its side to be sputter treated and a second layer located on its side not to be sputter treated, the first layer and the second layer having been bonded to each other through a bonding interface between the first layer and the second layer, the sputtering target satisfying the following requirements X and Y:
requirement X: A/B≦1.5 and
requirement Y: A/C≦1.5,

wherein A represents an oxygen peak value for the bonding interface; B represents an oxygen peak value for the first layer; and C represents an oxygen peak value for the second layer,

the process being characterized by comprising chemically etching the surface of a target material for constituting the second layer after or without flattening treatment to form a chemically etched face for constituting the bonding interface, then depositing powder of a target material for constituting the first layer by thermal spraying on the chemically etched face to form a layered deposit, and then subjecting the assembly to hot isostatic pressing (HIP) to diffusion-bond the first layer and the second layer to each other through the bonding interface.

Further, according to the present invention, there is provided a process for producing a sputtering target comprising a first layer located on its side to be sputter treated and a second layer located on its side not to be sputter treated, the first layer and the second layer having been bonded to each other through a bonding interface between the first layer and the second layer, the sputtering target satisfying the following requirements X and Y:
requirement X: A/B≦1.5 and
requirement Y: A/C≦1.5,

wherein A represents an oxygen peak value for the bonding interface; B represents an oxygen peak value for the first layer; and C represents an oxygen peak value for the second layer,

the process being characterized by comprising chemically etching the surface of a target material for constituting the second layer after or without flattening treatment to form a chemically etched face for constituting the bonding interface, then superimposing a plate-shaped target material for constituting the first layer onto the chemically etched face, and then subjecting the assembly to hot isostatic pressing (HIP) to diffusion-bond the target material for the first layer and the target material for the second layer to each other through the bonding interface.

In the process according to the present invention, preferably, a spent target material is used as a target material for constituting the second layer.

In the process according to the present invention, preferably, a spent target material subjected to or not subjected to flattening treatment and/or chemical etching is used as the target material for constituting the first layer.

### EFFECT OF THE INVENTION

The sputtering target according to the present invention comprises: a first layer located on its side to be sputter treated and a second layer located on its side not to be sputter treated, the first layer and the second layer having been bonded to each other through a bonding interface between the first layer and the second layer, wherein the oxygen peak value (A) for the bonding interface, the oxygen peak value (B) for the first layer, and the oxygen peak value (C) for the second layer satisfy specific requirements X and Y. This can realize effective suppression of the occurrence of abnormal discharge and splash to stably form a good thin film.

Thus, according to the present invention, spent sputtering targets, which, in many cases, have hitherto been discarded, can be recycled to effectively utilize resources, and, at the same time, the production cost of the sputtering target can be significantly lowered.

### BEST MODES FOR CARRYING OUT THE INVENTION

### Sputtering Target

The materials for constituting the sputtering target according to the present invention are not particularly limited. Accordingly, the sputtering target according to the present invention may comprise conventional various materials and, for example, may be formed of at least one of metals or ceramic materials, preferably formed of one of or a plurality of types of materials selected, for example, from molybdenum (Mo), tungsten (W), chromium (Cr), tantalum (Ta), titanium (Ti), aluminum (Al), silicon (Si), yttrium (Y), tungsten silicide (WSi), molybdenum silicide (MoSi), platinum (Pt)-manganese (Mn) alloys, and iridium (Ir)-manganese (Mn) alloys. Among them, specific examples of particularly preferred materials constituting the sputtering target according to the present invention include tungsten, molybdenum, titanium, iridium-manganese alloys, platinum-manganese alloys, chromium, and aluminum alloys. The raw material price of these materials is high, and, thus, reutilization of these materials can realize lowered cost.

In the sputtering target according to the present invention, the layer located on the sputtering target material in its side to be sputter treated (that is, a first layer) and the layer located on the sputtering target material in its side not to be sputter treated (that is, a second layer) are formed of the above various materials. In general, the first and second layers in the sputtering target according to the present invention are preferably identical to each other in the types of constituent materials and the ratio between the constituent materials. In some cases, however, for example, the ratio or type of the constituent materials may vary. The bonding interface in the sputtering target according to the present invention is present at a bonding part between the first and second layers and is derived from the surface of the second layer before first layer formation.

In a preferred embodiment of the sputtering target according to the present invention, (1) the first layer is formed of a layered deposit produced by depositing powder of a target material, for constituting the first layer, on the bonding interface. In a more preferred embodiment of the present invention, (2) the first layer is formed of a layered deposit produced by thermally spraying powder of a target material, for constituting the first layer, on the bonding interface. In another preferred embodiment of the present invention, (3) the first layer is formed of a plate-shaped target material for constituting the first layer.

In the above case (2), the powder of the target material for first layer formation may be thermally sprayed by any method. Preferred methods include, for example, flame spray, particularly ultrahigh speed flame spray and plasma spray.

When the sputtering target according to the present invention uses a waste target material for the reutilization of a spent waste target material, the waste target material can be used as a material for the formation of the second layer in the sputtering target according to the present invention. Alternatively, the waste target material may be used as the material for first layer formation and the material for second layer formation in the sputtering target according to the present invention. Specifically, in the production of the sputtering target according to the present invention, (4) a method may be adopted in which a spent target material may be used as the material for second layer formation followed by the formation of a fresh first layer on the second layer, or (5) a method may be adopted in which a first spent target material is used as a material for second layer formation followed by joining of a second spent target material onto the second layer.

Various target materials which are currently generally commercially available, distributed and discarded, for example, target materials produced by subjecting a sinter, produced by powder metallurgy, to hot isostatic pressing (HIP), and target materials produced by subjecting a sinter, produced by powder metallurgy, to hot working, may be used as the spent target material. Other extensive various target materials, for example, target materials produced by hot working an ingot produced by a melting process, may also be utilized. Sinters produced by powder metallurgy include those produced by a sintering method, a CIP method, or a hot pressing method.

(6) A further example of the material for second layer formation in the above cases (1) to (5) is such that, if necessary, another layer, which may be a spent target material or a freshly provided target material and may have a single-layer structure or a multilayer structure, has been further formed or joined. Accordingly, in this case, in the sputtering target according to the present invention, in addition to the bonding interface between the first and second layers, an additional bonding interface is sometimes present between the assembly and this another layer.

In the sputtering target according to the present invention including the above cases (1) to (6) and other cases, it is important that the following requirements X and Y be satisfied:
requirement X: A/B≦1.5, preferably A/B≦1.3 and
requirement Y: A/C≦1.5, preferably A/C≦1.3,

wherein A represents an oxygen peak value for the bonding interface between the first and second layers; B represents an oxygen peak value for the first layer; and C represents an oxygen peak value for the second layer.

When the requirements X and Y are not satisfied, the bonding interface is nonuniform, and, thus, the contemplated effect of the present invention cannot be attained without difficulties.

The above effect is more significant when, in addition to the above requirements X and Y, the following requirement Z is simultaneously satisfied.
Requirement Z: C/B≦1.5, preferably C/B≦1.3

Due to the nature of the sputtering target material, the surface of the target material is not fully specular, and the observation under a microscope reveals that fine concavoconvex shapes are observed on the surface of the sputtering material. For example, when the first and second layers have been diffusion bonded to each other, in some cases, the bonding interface between the first layer and the second layer is extended or widened in a given region in the thickness-wise direction by the diffusion of the target material for the first layer and/or the second layer. In view of the above facts, the oxygen peak value (A) at the bonding interface between the first and second layers in the present invention has been determined by linearly analyzing an oxygen peak for a region from the bonding interface as a base to a point distant by 100 μm in the direction of the depth (cross sectional direction) in each of the first and second layer. The oxygen peak value (B) for the first layer and the oxygen peak value (C) for the second layer means respectively an oxygen peak for a region excluding the region from the bonding interface as a base to a point distant by 100 μm in the direction of the depth (cross sectional direction) in the first layer, that is, a region from the point distant by 100 μm from the bonding interface in the direction of the depth (cross sectional direction) in the first layer to the distal end of the first layer remote from the bonding interface, and a an oxygen peak for a region excluding the region from the bonding interface as a base to a point distant by 100 μm in the direction of the depth (cross sectional direction) in the second layer, that is, a region from the point distant by 100 μm from the bonding interface in the direction of the depth (cross sectional direction) in the second layer to the distal end of the second layer remote from the bonding interface.

The oxygen peak value (A) for the bonding interface, the oxygen peak value (B) for the first layer, and the oxygen peak value (C) for the second layer each may be measured with an electron probe micro-analyzer (EPMA).

When the above requirements X and Y are not satisfied, in order to satisfy these requirements, treatment may be carried out for controlling or regulating one of or two or more of the oxygen peak value (A) for the bonding interface, the oxygen peak value (B) for the first layer, and the oxygen peak value (C) for the second layer. In the present invention, the above requirements X and Y may also be satisfied, for example, by controlling the oxygen peak value (C) for a waste target as the second layer or controlling the oxygen peak value (B) by varying conditions for first layer formation (for example, thermal spray conditions). The simplest and most efficient method is to control the oxygen peak value (A) for the bonding interface.

The most typical and preferred method used for this purpose is a method in which the surface of the target material for second layer formation is chemically etched before the formation or bonding of the first layer. Here the chemical etching in the present invention refers to surface treatment with an acid or alkali solution.

Before exposure to the chemical etching, the surface of the target material as the second layer may if necessary be treated for rendering the surface of the target material as the second layer smooth, for example, by mechanical polishing. When a waste target, which has been consumed by sputtering and has irregularities or concavoconvexes on its surface is used as a target material for second layer formation, smoothening is preferably carried out. By virtue of this, the occurrence of abnormal discharge or splash can be effectively suppressed, and a better thin film can be stably formed.

Simultaneously satisfying the above requirements X and Y and requirement Z is very difficult to realize by mere smoothening of the surface of the waste target by mechanical polishing. Accordingly, in this case, the above chemical etching treatment is indispensable.

As described above, the sputtering target according to the present invention comprises a first layer and a second layer bonded to each other through a bonding interface between the first and second layers. A sputtering target formed by diffusion bonding the target material for first layer formation to the target material for second layer formation is particularly preferred. This can realize denser bonding between the first layer and the second layer and in its turn can realize the production of a better sputtering target.

The diffusion bonding is preferably carried out by hot isostatic pressing (HIP). The target material for first layer formation and the target material for second layer formation are usually identical to each other in type. In the present invention, in order that the requirements X and Y are satisfied, for example, chemical etching treatment is carried out to control the oxygen peak value (A) for the bonding interface, the oxygen peak value (B) for the first layer, and the oxygen peak value (C) for the second layer so as to fall within the respective predetermined ranges. Therefore, the diffusion bonding between the first and second layers can be more efficiently and effectively realized by the hot isostatic pressing (HIP).

Preferred conditions for hot isostatic pressing (HIP) are as follows. Specifically, the temperature is preferably an HIP treatment temperature at which, at the present time, each material constituting the above various target materials is generally treated. For typical following materials, an example of a proper temperature range is as follows.

Molybdenum material: about 1000 to 1600° C., preferably 1100 to 1400° C.

Tungsten material: about 1400 to 2000° C., preferably 1500 to 1800° C.

Chromium material: about 800 to 1500° C., preferably 1000 to 1300° C.

Tantalum material: about 800 to 1500° C., preferably 1000 to 1300° C.

Titanium material: about 800 to 1500° C., preferably 1000 to 1300° C.

Aluminum material: about 200 to 600° C., preferably 300 to 500° C.

Silicon material: 800 to 1500° C., preferably 1000 to 1300° C.

Molybdenum-tungsten material: about 1000 to 1600° C., preferably 1200 to 1400° C.

Chromium-molybdenum material: about 800 to 1500° C., preferably 1000 to 1300° C.

Molybdenum-tantalum material: about 800 to 1500° C., preferably 1000 to 1300° C.

For all the above materials, when the HIP treatment temperature is below the lower limit of the HIP treatment temperature range, the temperature is too low to accelerate thermal activation at the contemplated bonding face, and, consequently, diffusion bonding by HIP is sometimes incomplete. Likewise, when the HIP treatment temperature is above the upper limit of HIP treatment temperature range, grain growth of the material takes place during the treatment. In this case, the sacrifice of a fundamental function as the target material, for example, particles disadvantageously occur during sputtering.

When the HIP treatment pressure is less than 40 MPa, the pressure is too low to accelerate activation at the contemplated bonding face, and, consequently, diffusion bonding by HIP is sometimes incomplete. Regarding the upper limit, when the pressure is more than 250 MPa, the burden on conventional HIP equipment is large due to its capability. Accordingly, the proper pressure range is not less than 40 MPa and not more than 250 MPa.

The HIP treatment time is preferably in the range of 1 to 6 hr. When the HIP treatment time is less than one hr, the thermal activation at the bonding face is not accelerated, and, consequently, the bonding strength is disadvantageously lowered. On the other hand, when the HIP treatment time exceeds the upper limit of the HIP treatment time, that is, 6 hr, diffusion bonding between both the first and second layers is satisfactorily completed. Accordingly, in this case, further treatment is disadvantageous from the viewpoints of energy and workability.

<Production Process of Sputtering Target>

The sputtering target according to the present invention may be produced by any desired method. For example, the following methods may be mentioned as particularly preferred methods for producing the sputtering target according to the present invention.
(1) A process for producing a sputtering target, comprising chemically etching the surface of a target material for constituting the second layer after or without flattening treatment to form a chemically etched face for constituting the bonding interface, and depositing powder of a target material for constituting the first layer by thermal spraying on the chemically etched face to form a layered deposit and thus to bond the first layer and the second layer through the bonding interface.
(2) A process for producing a sputtering target, comprising chemically etching the surface of a target material for constituting the second layer after or without flattening treatment to form a chemically etched face for constituting the bonding interface, then depositing powder of a target material for constituting the first layer by thermal spraying on the chemically etched face to form a layered deposit, and then subjecting the assembly to hot isostatic pressing (HIP) to diffusion-bond the first layer and the second layer to each other through the bonding interface.
(3) A process for producing a sputtering target, comprising chemically etching the surface of a target material for constituting the second layer after or without flattening treatment to form a chemically etched face for constituting the bonding interface, then superimposing a plate-shaped target material for constituting the first layer onto the chemically etched face, and then subjecting the assembly to hot isostatic pressing (HIP) to diffusion-bond the target material for the first layer and the target material for the second layer to each other through the bonding interface.
(4) A process for producing a sputtering target, wherein, in any one of the above processes (1) to (3), a spent target material is used as a target material for constituting the second layer.
(5) A process for producing a sputtering target, wherein, in the above process (4), a spent target material subjected to or not subjected to flattening treatment and/or chemical etching is used as the target material for constituting the first layer.

### EXAMPLES

### Example 1

A spent sputtering target formed of an aluminum (Al) material containing 2 at % of yttrium (Y) (diameter 300 mm, average thickness 15 mm) was machined to remove a convex part present on its surface. This spent sputtering target was provided as a second layer, and the machined surface was chemically etched. Thereafter, particles of an aluminum material containing 2 at % of yttrium were deposited onto the chemically etched face by ultrahigh speed flame spraying to a thickness of about 15 mm to form a first layer. Thus, a sputtering target according to the present invention was produced.

A sample piece was extracted from arbitrary three places in this sputtering target. These sample pieces were analyzed by EPMA for an oxygen peak for the first layer, the second layer, and the bonding interface between the first layer and the second layer. The results are shown in Table 1.

Further, a target having a size of 50 mm in diameter×5 mm in thickness was extracted from the above sputtering target. This target was mounted on a sputtering apparatus, and dummy sputtering was carried out under the following film forming conditions for 30 min. Thereafter, a splash test was carried out ten times. The average of data obtained by the 10-time test is shown in Table 1.

Conditions for film formation: argon (Ar) flow rate 10 scm, power 180 W, TS distance: 75 mm, sputtering pressure: 0.3 Pa, substrate temperature: R.T, and film thickness: 300 nm.

### Example 2

A sputtering target according to the present invention was produced in the same manner as in Example 1, except that the machining was not carried out. In the same manner as in Example 1, the measurement of the oxygen peak in each of the first layer, the second layer, and the bonding interface and a splash test were carried out. The results are shown in Table 1.

### Example 3

In the same manner as in Example 1, a spent sputtering target formed of an aluminum material containing 2 at % of yttrium (diameter 300 mm, average thickness 15 mm) was machined to remove a convex part present on its surface. This spent sputtering target was provided as a second layer, and the machined surface was chemically etched. Thereafter, particles of an aluminum material containing 2 at % of yttrium were deposited onto the chemically etched face by ultrahigh speed flame spraying to a thickness of about 30 mm to form a first layer. The assembly was then subjected to HIP to produce an about 30 mm-thick sputtering target according to the present invention.

In the same manner as in Example 1, the measurement of the oxygen peak in each of the first layer, the second layer, and the bonding interface and a splash test were carried out. The results are shown in Table 1.

### Example 4

A sputtering target according to the present invention was produced in the same manner as in Example 3, except that the machining was not carried out. In the same manner as in Example 1, the measurement of the oxygen peak in each of the first layer, the second layer, and the bonding interface and a splash test were carried out. The results are shown in Table 1.

### Comparative Examples 1 to 4

Sputtering targets (Comparative Examples 1 to 4) were produced in the same manner as in Examples 1 to 4, except that, as shown in Table 1, the chemical etching was not carried out. For each of the sputtering targets thus obtained, the measurement of the oxygen peak in each of the first layer, the second layer, and the bonding interface and a splash test were carried out in the same manner as in Example 1. The results are shown in Table 1.

### Examples 5 to 8 and Comparative Examples 5 to 8

Sputtering targets (Examples 5 to 8 and Comparative Examples 5 to 8) were produced in the same manner as in Examples 1 to 4 and Comparative Examples 1 to 4, except that, as shown in Table 1, a spent sputtering target formed of an aluminum material containing 0.6 at % of yttrium was used.

For each of the sputtering targets thus obtained, the measurement of the oxygen peak in each of the first layer, the second layer, and the bonding interface and a splash test were carried out in the same manner as described above. The results are shown in Table 1.

### Examples 9 to 12 and Comparative Examples 9 to 12

Sputtering targets (Examples 9 to 12 and Comparative Examples 9 to 12) were produced in the same manner as in Examples 1 to 4 and Comparative Examples 1 to 4, except that, as shown in Table 1, a spent sputtering target formed of a chromium (Cr) material was used.

For each of the sputtering targets thus obtained, the measurement of the oxygen peak in each of the first layer, the second layer, and the bonding interface and a splash test were carried out in the same manner as described above. The results are shown in Table 1.

### Examples 13 to 16 and Comparative Examples 13 to 16

Sputtering targets (Examples 13 to 16 and Comparative Examples 13 to 16) were produced in the same manner as in Examples 1 to 4 and Comparative Examples 1 to 4, except that, as shown in Table 1, a spent sputtering target formed of a silicon (Si) material was used. For each of the sputtering targets thus obtained, the measurement of the oxygen peak in the first layer, the second layer, and the bonding interface and a splash test were carried out in the same manner as described above. The results are shown in Table 1.

### Examples 17 to 20 and Comparative Examples 17 to 20

Sputtering targets (Examples 17 to 20 and Comparative Examples 17 to 20) were produced in the same manner as in Examples 1 to 4 and Comparative Examples 1 to 4, except that, as shown in Table 1, a spent sputtering target formed of a chromium (Cr) material was used.

For each of the sputtering targets thus obtained, the measurement of the oxygen peak in each of the first layer, the second layer, and the bonding interface and a splash test were carried out in the same manner as described above. The results are shown in Table 1.

### Example 21

A spent sputtering target formed of an aluminum (Al) material containing 2 at % of yttrium (Y) (diameter 300 mm, average thickness 15 mm) was machined to remove a convex part present on its surface. This spent sputtering target was provided as a second layer, and the machined surface was chemically etched. On the other hand, another spent sputtering target formed of the same material as described above and subjected to the same machining as described above was provided as a first layer. The first layer was superimposed on the spent sputtering target as the second layer, followed by HIP treatment to provide a sputtering target according to the present invention. The superimposition of two spent waste sputtering targets on top of each other is described as “pattern 1-1” in Table 2.

In the same manner as in Example 1, the measurement of the oxygen peak in the first layer, the second layer, and the bonding interface and a splash test were carried out. The results are shown in Table 2.

### Example 22

In the same manner as in Example 21, a spent sputtering target formed of an aluminum (Al) material containing 2 at % of yttrium (Y) (diameter 300 mm, average thickness 15 mm) was machined to remove a convex part present on its surface. This spent sputtering target was provided as a second layer, and the machined surface was chemically etched.

On the other hand, one sputtering target formed of the same material as described above except that the material is fresh and unused, was provided as a first layer. The first layer and the spent sputtering target as the second layer were superimposed on top of each other, followed by HIP treatment to produce a sputtering target according to the present invention. The superimposition of a spent waste sputtering target and an unused sputtering target on top of each other is described as “pattern 1-2” in Table 2.

In the same manner as in Example 1, the measurement of the oxygen peak in the first layer, the second layer, and the bonding interface and a splash test were carried out. The results are shown in Table 2.

### Example 23

In the same manner as in Example 21, a spent sputtering target formed of an aluminum (Al) material containing 2 at % of yttrium (Y) (diameter 300 mm, average thickness 15 mm) was machined to remove a convex part present on its surface. This spent sputtering target was provided as a second layer, and the machined surface was chemically etched.

A second layer formed of the same type of a powder material as described above was formed on the second layer formed of the spent sputtering target, followed by HIP treatment to produce a sputtering target according to the present invention, comprising the second layer formed of the spent sputtering target and the second layer formed of the same type of a powder material as described above provided on the second layer. The provision of the layer formed of a powder material (second layer) on the machined, spent and waste sputtering target (first layer) is described as “pattern 2-1” in Table 2.

In the same manner as in Example 1, the measurement of the oxygen peak in the first layer, the second layer, and the bonding interface and a splash test were carried out. The results are shown in Table 2.

### Example 24

A sputtering target according to the present invention was produced in the same manner as in Example 23, except that the machining was not carried out. In the same manner as in Example 1, the measurement of the oxygen peak in the first layer, the second layer, and the bonding interface and a splash test were carried out. The results are shown in Table 1.

### Comparative Examples 21 to 24

Sputtering targets (Comparative Examples 21 to 24) were produced in the same manner as in Examples 21 to 24, except that, as shown in Table 2, the chemical etching was not carried out.

For each of the sputtering targets thus obtained, the measurement of the oxygen peak in each of the first layer, the second layer, and the bonding interface and a splash test were carried out in the same manner as in Example 1. The results are shown in Table 2. The provision of the layer formed of a powder material (second layer) on the unmachined, spent and waste sputtering target (first layer) is described as “pattern 2-2” in Table 2.

### Examples 25 to 28 and Comparative Examples 25 to 28

Sputtering targets (Examples 25 to 28 and Comparative Examples 25 to 28) were produced in the same manner as in Examples 21 to 24 and Comparative Examples 21 to 24, except that, as shown in Table 2, a spent sputtering target formed of an aluminum (Al) material containing 0.6 at % of yttrium (Y) was used.

For each of the sputtering targets thus obtained, the measurement of the oxygen peak in each of the first layer, the second layer, and the bonding interface and a splash test were carried out in the same manner as in Example 1. The results are shown in Table 2.

### Examples 29 to 32 and Comparative Examples 29 to 32

Sputtering targets (Examples 29 to 32 and Comparative Examples 29 to 32) were produced in the same manner as in Examples 21 to 24 and Comparative Examples 21 to 24, except that, as shown in Table 2, a spent sputtering target formed of a chromium (Cr) material was used.

For each of the sputtering targets thus obtained, the measurement of the oxygen peak in each of the first layer, the second layer, and the bonding interface and a splash test were carried out in the same manner as in Example 1. The results are shown in Table 2.

### Examples 33 to 36 and Comparative Examples 33 to 36

Sputtering targets (Examples 33 to 36 and Comparative Examples 33 to 36) were produced in the same manner as in Examples 21 to 24 and Comparative Examples 21 to 24, except that, as shown in Table 2, a spent sputtering target formed of a silicon (Si) material was used.

For each of the sputtering targets thus obtained, the measurement of the oxygen peak in the first layer, the second layer, and the bonding interface and a splash test were carried out in the same manner as in Example 1. The results are shown in Table 2.

TABLE 1

| Experi- | | Production | | | Oxygen | | |
|---|---|---|---|---|---|---|---|
| mental | | Second layer + first | | Chemical | peak | | |
| Example | Material | layer | HIP | etching | A/B | A/C | Splash |
| Ex. 1 | Al-2 at % Y | Waste material (treated) + | Not done | Done | 1.25 | 1.34 | 7 |
| | | flame sprayed | | | | | |
| Ex. 2 | Al-2 at % Y | Waste material (not treated) + | Not done | Done | 1.32 | 1.41 | 8 |
| | | flame sprayed | | | | | |
| Ex. 3 | Al-2 at % Y | Waste material (treated) + | Done | Done | 1.08 | 1.12 | 4 |
| | | flame sprayed | | | | | |
| Ex. 4 | Al-2 at % Y | Waste material (not treated) + | Done | Done | 1.06 | 1.14 | 3 |
| | | flame sprayed | | | | | |
| Comp. | Al-2 at % Y | Waste material (treated) + | Not done | Not done | 1.68 | 1.39 | 34 |
| Ex. 1 | | flame sprayed | | | | | |
| Comp. | Al-2 at % Y | Waste material (not treated) + | Not done | Not done | 1.62 | 1.29 | 31 |
| Ex. 2 | | flame sprayed | | | | | |
| Comp. | Al-2 at % Y | Waste material (treated) + | Done | Not done | 1.69 | 1.07 | 24 |
| Ex. 3 | | flame sprayed | | | | | |
| Comp. | Al-2 at % Y | Waste material (not treated) + | Done | Not done | 1.55 | 1.06 | 28 |
| Ex. 4 | | flame sprayed | | | | | |
| Ex. 5 | Al-0.6 at % Y | Waste material (treated) + | Not done | Done | 1.23 | 1.35 | 6 |
| | | flame sprayed | | | | | |
| Ex. 6 | Al-0.6 at % Y | Waste material (not treated) + | Not done | Done | 1.34 | 1.4 | 10 |
| | | flame sprayed | | | | | |
| Ex. 7 | Al-0.6 at % Y | Waste material (treated) + | Done | Done | 1.09 | 1.18 | 5 |
| | | flame sprayed | | | | | |
| Ex. 8 | Al-0.6 at % Y | Waste material (not treated) + | Done | Done | 1.05 | 1.19 | 2 |
| | | flame sprayed | | | | | |
| Comp. | Al-0.6 at % Y | Waste material (treated) + | Not done | Not done | 1.70 | 1.38 | 37 |
| Ex. 5 | | flame sprayed | | | | | |
| Comp. | Al-0.6 at % Y | Waste material (not treated) + | Not done | Not done | 1.68 | 1.27 | 36 |
| Ex. 6 | | flame sprayed | | | | | |
| Comp. | Al-0.6 at % Y | Waste material (treated) + | Done | Not done | 1.65 | 1.01 | 28 |
| Ex. 7 | | flame sprayed | | | | | |
| Comp. | Al-0.6 at % Y | Waste material (not treated) + | Done | Not done | 1.54 | 1.05 | 25 |
| Ex. 8 | | flame sprayed | | | | | |
| Ex. 9 | Cr | Waste material (treated) + | Not done | Done | 1.28 | 1.32 | 7 |
| | | flame sprayed | | | | | |
| Ex. 10 | Cr | Waste material (not treated) + | Not done | Done | 1.36 | 1.44 | 9 |
| | | flame sprayed | | | | | |
| Ex. 11 | Cr | Waste material (treated) + | Done | Done | 1.05 | 1.33 | 6 |
| | | flame sprayed | | | | | |
| Ex. 12 | Cr | Waste material (not treated) + | Done | Done | 1.03 | 1.21 | 3 |
| | | flame sprayed | | | | | |
| Comp. | Cr | Waste material (treated) + | Not done | Not done | 1.76 | 1.24 | 34 |
| Ex. 9 | | flame sprayed | | | | | |
| Comp. | Cr | Waste material (not treated) + | Not done | Not done | 1.77 | 1.32 | 33 |
| Ex. 10 | | flame sprayed | | | | | |
| Comp. | Cr | Waste material (treated) + | Done | Not done | 1.54 | 1.03 | 25 |
| Ex. 11 | | flame sprayed | | | | | |
| Comp. | Cr | Waste material (not treated) + | Done | Not done | 1.59 | 1.06 | 27 |
| Ex. 12 | | flame sprayed | | | | | |
| Ex. 13 | Si | Waste material (treated) + | Not done | Done | 1.31 | 1.29 | 6 |
| | | flame sprayed | | | | | |
| Ex. 14 | Si | Waste material (not treated) + | Not done | Done | 1.29 | 1.39 | 10 |
| | | flame sprayed | | | | | |
| Ex. 15 | Si | Waste material (treated) + | Done | Done | 0.98 | 1.36 | 7 |
| | | flame sprayed | | | | | |
| Ex. 16 | Si | Waste material (not treated) + | Done | Done | 0.94 | 1.28 | 4 |
| | | flame sprayed | | | | | |
| Comp. | Si | Waste material (treated) + | Not done | Not done | 1.77 | 1.37 | 33 |
| Ex. 13 | | flame sprayed | | | | | |
| Comp. | Si | Waste material (not treated) + | Not done | Not done | 1.8 | 1.29 | 38 |
| Ex. 14 | | flame sprayed | | | | | |
| Comp. | Si | Waste material (treated) + | Done | Not done | 1.59 | 0.99 | 29 |
| Ex. 15 | | flame sprayed | | | | | |
| Comp. | Si | Waste material (not treated) + | Done | Not done | 1.62 | 0.97 | 24 |
| Ex. 16 | | flame sprayed | | | | | |
| Ex. 17 | Si | Waste material (treated) + | Not done | Done | 1.29 | 1.18 | 5 |
| | | plasma sprayed | | | | | |
| Ex. 18 | Si | Waste material (not treated) + | Not done | Done | 1.32 | 1.21 | 11 |
| | | plasma sprayed | | | | | |
| Ex. 19 | Si | Waste material (treated) + | Done | Done | 1.01 | 1.32 | 9 |
| | | plasma sprayed | | | | | |
| Ex. 20 | Si | Waste material (not treated) + | Done | Done | 1.06 | 1.19 | 3 |
| | | plasma sprayed | | | | | |
| Comp. | Si | Waste material (treated) + | Not done | Not done | 1.89 | 1.41 | 36 |
| Ex. 17 | | plasma sprayed | | | | | |
| Comp. | Si | Waste material (not treated) + | Not done | Not done | 1.93 | 1.36 | 41 |
| Ex. 18 | | plasma sprayed | | | | | |
| Comp. | Si | Waste material (treated) + | Done | Not done | 1.75 | 0.97 | 32 |
| Ex. 19 | | plasma sprayed | | | | | |
| Comp. | Si | Waste material (not treated) + | Done | Not done | 1.81 | 0.99 | 29 |
| Ex. 20 | | plasma sprayed | | | | | |

TABLE 2

| Experi- | | Production | | | | Oxygen | | |
|---|---|---|---|---|---|---|---|---|
| mental | | | First layer + second | | Chemical | peak | | |
| Example | Material | Pattern | layer | HIP | etching | A/B | A/C | Splash |
| Ex. 21 | Al-2 at % Y | 1-1 | Waste material (treated) + | Done | Done | 1.07 | 0.99 | 3 |
| | | | waste material (treated) | | | | | |
| Ex. 22 | Al-2 at % Y | 1-2 | Waste material (treated) + | Done | Done | 0.99 | 0.92 | 4 |
| | | | new material | | | | | |
| Ex. 23 | Al-2 at % Y | 2-1 | Waste material (treated) + | Done | Done | 1.03 | 1.04 | 2 |
| | | | powder | | | | | |
| Ex. 24 | Al-2 at % Y | 2-2 | Waste material (not | Done | Done | 0.97 | 1.06 | 3 |
| | | | treated) + powder | | | | | |
| Comp. | Al-2 at % Y | 1-1 | Waste material (treated) + | Done | Not done | 1.57 | 1.01 | 19 |
| Ex. 21 | | | waste material (treated) | | | | | |
| Comp. | Al-2 at % Y | 1-2 | Waste material (treated) + | Done | Not done | 1.54 | 0.98 | 21 |
| Ex. 22 | | | new material | | | | | |
| Comp. | Al-2 at % Y | 2-1 | Waste material (treated) + | Done | Not done | 1.61 | 1.10 | 23 |
| Ex. 23 | | | powder | | | | | |
| Comp. | Al-2 at % Y | 2-2 | Waste material (not | Done | Not done | 1.59 | 1.09 | 26 |
| Ex. 24 | | | treated) + powder | | | | | |
| Ex. 25 | Al-0.6 at % Y | 1-1 | Waste material (treated) + | Done | Done | 0.98 | 0.97 | 2 |
| | | | waste material (treated) | | | | | |
| Ex. 26 | Al-0.6 at % Y | 1-2 | Waste material (treated) + | Done | Done | 1.01 | 0.95 | 3 |
| | | | new material | | | | | |
| Ex. 27 | Al-0.6 at % Y | 2-1 | Waste material (treated) + | Done | Done | 0.96 | 1.03 | 3 |
| | | | powder | | | | | |
| Ex. 28 | Al-0.6 at % Y | 2-2 | Waste material (not | Done | Done | 0.99 | 1.05 | 4 |
| | | | treated) + powder | | | | | |
| Comp. | Al-0.6 at % Y | 1-1 | Waste material (treated) + | Done | Not done | 1.62 | 1.04 | 21 |
| Ex. 25 | | | waste material (treated) | | | | | |
| Comp. | Al-0.6 at % Y | 1-2 | Waste material (treated) + | Done | Not done | 1.58 | 0.99 | 24 |
| Ex. 26 | | | new material | | | | | |
| Comp. | Al-0.6 at % Y | 2-1 | Waste material (treated) + | Done | Not done | 1.59 | 1.11 | 27 |
| Ex. 27 | | | powder | | | | | |
| Comp. | Al-0.6 at % Y | 2-2 | Waste material (not | Done | Not done | 1.54 | 1.06 | 29 |
| Ex. 28 | | | treated) + powder | | | | | |
| Ex. 29 | Cr | 1-1 | Waste material (treated) + | Done | Done | 0.99 | 0.99 | 1 |
| | | | waste material (treated) | | | | | |
| Ex. 30 | Cr | 1-2 | Waste material (treated) + | Done | Done | 1.04 | 0.98 | 5 |
| | | | new material | | | | | |
| Ex. 31 | Cr | 2-1 | Waste material (treated) + | Done | Done | 1.01 | 1.04 | 4 |
| | | | powder | | | | | |
| Ex. 32 | Cr | 2-2 | Waste material (not | Done | Done | 0.98 | 1.06 | 7 |
| | | | treated) + powder | | | | | |
| Comp. | Cr | 1-1 | Waste material (treated) + | Done | Not done | 1.71 | 1.07 | 20 |
| Ex. 29 | | | waste material (treated) | | | | | |
| Comp. | Cr | 1-2 | Waste material (treated) + | Done | Not done | 1.62 | 1.02 | 22 |
| Ex. 30 | | | new material | | | | | |
| Comp. | Cr | 2-1 | Waste material (treated) + | Done | Not done | 1.6 | 1.09 | 24 |
| Ex. 31 | | | powder | | | | | |
| Comp. | Cr | 2-2 | Waste material (not | Done | Not done | 1.59 | 0.97 | 30 |
| Ex. 32 | | | treated) + powder | | | | | |
| Ex. 33 | Si | 1-1 | Waste material (treated) + | Done | Done | 0.98 | 0.98 | 3 |
| | | | waste material (treated) | | | | | |
| Ex. 34 | Si | 1-2 | Waste material (treated) + | Done | Done | 1.01 | 0.96 | 4 |
| | | | new material | | | | | |
| Ex. 35 | Si | 2-1 | Waste material (treated) + | Done | Done | 1.05 | 1.01 | 5 |
| | | | powder | | | | | |
| Ex. 36 | Si | 2-2 | Waste material (not | Done | Done | 0.99 | 1.03 | 6 |
| | | | treated) + powder | | | | | |
| Comp. | Si | 1-1 | Waste material (treated) + | Done | Not done | 1.82 | 1.04 | 22 |
| Ex. 33 | | | waste material (treated) | | | | | |
| Comp. | Si | 1-2 | Waste material (treated) + | Done | Not done | 1.73 | 1.03 | 23 |
| Ex. 34 | | | new material | | | | | |
| Comp. | Si | 2-1 | Waste material (treated) + | Done | Not done | 1.66 | 1.07 | 25 |
| Ex. 35 | | | powder | | | | | |
| Comp. | Si | 2-2 | Waste material (not | Done | Not done | 1.83 | 0.99 | 31 |
| Ex. 36 | | | treated) + powder | | | | | |

1. A sputtering target comprising: a first layer located on its side to be sputter treated and a second layer located on its side not to be sputter treated, the first layer and the second layer having been bonded to each other through a bonding interface between the first layer and the second layer, the sputtering target satisfying the following requirements X and Y:
requirement X: A/B≦1.5 and
requirement Y: A/C≦1.5,
wherein A represents an oxygen peak value for the bonding interface; B represents an oxygen peak value for the first layer; and C represents an oxygen peak value for the second layer.

2. The sputtering target according to claim 1, which further satisfies the following requirement Z:
requirement Z: C/B≦1.5.

3. The sputtering target according to claim 1, wherein the first layer is formed of a layered deposit produced by depositing powder of a target material, for constituting the first layer, on the bonding interface.

4. The sputtering target according to claim 1, wherein the first layer is formed of a layered deposit produced by thermally spraying powder of a target material, for constituting the first layer, on the bonding interface.

5. The sputtering target according to claim 1, wherein the first layer is formed of a plate-shaped target material for constituting the first layer.

6. The sputtering target according to claim 1, which is formed by diffusion bonding a target material for constituting the first layer and a target material for constituting the second layer by hot isostatic pressing (HIP).

7. The sputtering target according to claim 1, wherein the bonding interface has been formed by chemically etching the surface of a target material for constituting the second layer before the formation or bonding of the first layer.

8. The sputtering target according to claim 1, which further comprises a further layer distinguished from the first layer and the second layer and another bonding interface provided between the first and/or second layer and the further layer.

9. A process for producing a sputtering target comprising a first layer located on its side to be sputter treated and a second layer located on its side not to be sputter treated, the first layer and the second layer having been bonded to each other through a bonding interface between the first layer and the second layer, the sputtering target satisfying the following requirements X and Y:
requirement X: A/B≦1.5 and
requirement Y: A/C≦1.5,
wherein A represents an oxygen peak value for the bonding interface; B represents an oxygen peak value for the first layer; and C represents an oxygen peak value for the second layer,
the process comprising chemically etching the surface of a target material for constituting the second layer after or without flattening treatment to form a chemically etched face, which is the bonding interface, and depositing powder of a target material for constituting the first layer by thermal spraying on the chemically etched face to form a layered deposit and thus to bond the first layer and the second layer through the bonding interface.

10. A process for producing a sputtering target comprising a first layer located on its side to be sputter treated and a second layer located on its side not to be sputter treated, the first layer and the second layer having been bonded to each other through a bonding interface between the first layer and the second layer, the sputtering target satisfying the following requirements X and Y:
requirement X: A/B≦1.5 and
requirement Y: A/C≦1.5,
wherein A represents an oxygen peak value for the bonding interface; B represents an oxygen peak value for the first layer; and C represents an oxygen peak value for the second layer,
the process comprising chemically etching the surface of a target material for constituting the second layer after or without flattening treatment to form a chemically etched face for constituting the bonding interface, then depositing powder of a target material for constituting the first layer by thermal spraying on the chemically etched face to form a layered deposit, and then subjecting the assembly to hot isostatic pressing (HIP) to diffusion-bond the first layer and the second layer to each other through the bonding interface.

11. A process for producing a sputtering target comprising a first layer located on its side to be sputter treated and a second layer located on its side not to be sputter treated, the first layer and the second layer having been bonded to each other through a bonding interface between the first layer and the second layer, the sputtering target satisfying the following requirements X and Y:
requirement X: A/B≦1.5 and
requirement Y: A/C≦1.5,
wherein A represents an oxygen peak value for the bonding interface; B represents an oxygen peak value for the first layer; and C represents an oxygen peak value for the second layer,
the process comprising chemically etching the surface of a target material for constituting the second layer after or without flattening treatment to form a chemically etched face for constituting the bonding interface, then superimposing a plate-shaped target material for constituting the first layer onto the chemically etched face, and then subjecting the assembly to hot isostatic pressing (HIP) to diffusion-bond the target material for the first layer and the target material for the second layer to each other through the bonding interface.

12. The process according to claim 9, wherein a spent target material is used as a target material for constituting the second layer.

13. The process according to claim 12, wherein a spent target material subjected to or not subjected to flattening treatment and/or chemical etching is used as the target material for constituting the first layer.
